(19) United States
(12) Patent Application Publication
(10) Pub. No.: US 2025/0323744 A1
(43) Pub. Date: Oct. 16, 2025

(54) APPARATUS TO SYNTONIZE TIMING DEVICES

(71) Applicants: Mahibur Rahman, Chandler, AZ (US); Christopher Hall, Portland, OR (US); David Mccall, Dallas, TX (US)

(72) Inventors: Mahibur Rahman, Chandler, AZ (US); Christopher Hall, Portland, OR (US); David Mccall, Dallas, TX (US)

(21) Appl. No.: 19/253,140

(22) Filed: Jun. 27, 2025

(51) Int. Cl. H04J 3/06

(52) U.S. Cl. CPC H04J 3/0667; H04J 3/0617

(57) ABSTRACT

Apparatus are disclosed to syntonize timing devices. An example apparatus includes activity detection circuitry to generate a pulse output based on a first clock and a second clock, the pulse output having a periodicity of the first clock, phase error generation circuitry to determine phase error direction indicators between the pulse output and a regenerated clock, the regenerated clock having a first frequency, proportional/integral (PI) circuitry to determine correction values based on the phase error direction indicators, the correction values to cause modification of the first frequency of the regenerated clock, and precision time protocol (PTP) timer circuitry to modify a frequency of a third clock based on accumulated ones of the correction values.

### BACKGROUND

Multi-device operation includes coordination between devices to perform operations relative to a time reference. Time reference information, such as a time-of-day (TOD) value having year information, month information, day information, and/or time information, may be obtained by devices via network communication. In some circumstances, devices include global navigation satellite system (GNSS) circuitry to obtain time reference information with sub nano-second accuracy.

### BRIEF DESCRIPTION OF THE DRAWINGS

FIG. 1 is a block diagram of an example environment in which example syntonization circuitry operates to syntonize timing devices.

FIG. 2 is a block diagram of an example implementation of the syntonization circuitry of FIG. 1 to syntonize timing devices in accordance with teachings disclosed herein.

FIG. 3 is a block diagram of activity detection circuitry of FIG. 2 to syntonize timing devices in accordance with teachings disclosed herein.

FIG. 4A is a block diagram of phase error generation circuitry of FIG. 2 to syntonize timing devices in accordance with teachings disclosed herein.

FIG. 4B is a block diagram of phase error generation circuitry of FIG. 2 to syntonize timing devices in accordance with teachings disclosed herein.

FIG. 4C is a block diagram of accumulated phase error generation circuitry of FIG. 2 to syntonize timing devices in accordance with teachings disclosed herein.

FIG. 5 is a block diagram of loop filter circuitry of FIG. 2 to syntonize timing devices in accordance with teachings disclosed herein.

FIG. 6 is a block diagram of proportional/integral (PI) circuitry of FIG. 2 to syntonize timing devices in accordance with teachings disclosed herein.

FIG. 7 is a block diagram of numerically controlled oscillator (NCO) circuitry of FIG. 2 to syntonize timing devices in accordance with teachings disclosed herein.

FIG. 8 is a block diagram of frequency lock detection circuitry of FIG. 2 to syntonize timing devices in accordance with teachings disclosed herein.

FIG. 9 is a table of example settling times corresponding to different reference clock rates and target accuracy values achieved by the example syntonization circuitry of FIGS. 1-3, 4A-4C and 5-8.

FIG. 10 illustrates example waveforms of simulated tracking behavior of the example syntonization circuitry of FIGS. 1 and 2.

FIGS. 11-15 are flowcharts representative of example operations that may instantiated and/or performed by the example syntonization circuitry of FIGS. 1-3, 4A-4C and 5-8 to syntonize timing devices.

FIG. 16 is a block diagram of example field programmable gate array (FPGA) circuitry of structured to instantiate and/or perform operations of the syntonization circuitry of FIG. 2.

In general, the same reference numbers will be used throughout the drawing(s) and accompanying written description to refer to the same or like parts. The figures are not necessarily to scale.

### DETAILED DESCRIPTION

Device-to-device communication over a network, such as audio/video (A/V) streaming and/or industrial automation, may require deterministic communication. Some devices expect an accurate time value (e.g., a time-of-day (TOD) clock value) to be shared so that distributed operations and/or events are coordinated and/or logged in a consistent manner. Efforts to configure two or more devices to represent a same time are referred to as synchronization. One example of time synchronization in a network environment is defined by IEEE 802.1, which is part of time sensitive networking (TSN), which is defined by various IEEE 802.1 specifications to aid in deterministic performance and network traffic prioritization. For instance, if a primary clock operates with a relatively high degree of accuracy (e.g., atomic time references based on a resonant frequency of atoms), then IEEE 802.1 “synchronizes” time reference values in other devices (e.g., having secondary clocks) with the time value of the primary clock.

However, the secondary clocks may not include circuitry with atomic-based accuracy capabilities and, instead, may utilize relatively less expensive crystal-based circuitry. As such, one or more secondary clocks exhibit frequency drift that causes a phase difference from the primary clock. In other words, secondary clocks may not be syntonized with the primary clocks. Unlike synchronization, which reflects an accurate time value (e.g., a time stamp of date/hour/minute/second), “syntonization” reflects deviation/drift of frequency between clocks. Stated differently, while clocks may not be synchronized in time (e.g., lack time parity), those same clocks may still be syntonized such that they exhibit no phase difference. In some examples, clocks may be synchronized at a first moment in which two or more clocks represent a same time value, but if such clocks exhibit phase differences (e.g., a lack of syntonization), then eventually the time values between such clocks will deviate. As such, while a secondary clock may exhibit an aligned frequency with a primary clock for a number of cycles, because of the relatively less accurate crystal-based circuitry the frequency of the secondary clock will drift (e.g., due to temperature and/or voltage variation).

Efforts to perform time critical tasks that comply with TSN expectations have been implemented with software solutions of a computing resource (e.g., CPU software intervention, system-on-chip (SoC) TSN, etc.). Known software based approaches to implement TSN and/or otherwise IEEE 802.1 compliant techniques utilize computing resources (e.g., a CPU), which may be better utilized by performing other tasks. Additionally, known TSN techniques that are implemented by software based approaches exhibit a startup initialization delay/lag when a computing platform is activated. The known software based approaches attempt to time stamp external reference clock sources having a relatively high degree of accuracy (e.g., <0.1 ppm frequency resolution) to a local clock (e.g., an internal network interface controller (NIC) clock source). However, known software based frequency error tracking is limited to tracking at relatively lower tracking rates (e.g., 1 to 10 Hz) while supporting relatively low external reference clock rates (e.g., 1 pulse-per-second), which results in relatively longer settling times when compared to hardware based approaches of some examples disclosed herein. Known software based approaches also struggle to track relatively higher reference clock rates of 10 MHz, and suffer from software interrupts that affect precise scheduling, exhibit writing overhead, and cause jitter effects.

Some hardware based examples disclosed herein facilitate syntonization of clocks between devices and/or syntonization of clocks within a same device. Some hardware based examples disclosed herein enable Precision Time Protocol (PTP) clock devices (e.g., IEEE 1588 compliant) to be syntonized to an external reference clock source that may exhibit a relatively high degree of accuracy (e.g., <0.1 ppm frequency resolution). Some hardware based examples disclosed herein enable relatively less expensive hardware circuitry (e.g., 100 ppm crystal oscillators) to syntonize clocks without assistance from a central processing unit (CPU). Some hardware based examples disclosed herein monitor frequency between the secondary clock and the primary clock (e.g., a reference clock) to identify a threshold phase difference, and react to the occurrence of the threshold phase difference to cause a correction in a PTP clock (e.g., frequency increment metrics or frequency decrement metrics (e.g., increment time pulses or decrement time pulses) to bring a frequency of the PTP clock into syntonization with the reference clock). Additionally, correction metrics derived by some hardware based examples disclosed herein may be transmitted and/or otherwise propagated to other nodes within a TSN network to cause their respective clocks to operate in a manner syntonized with the reference clock.

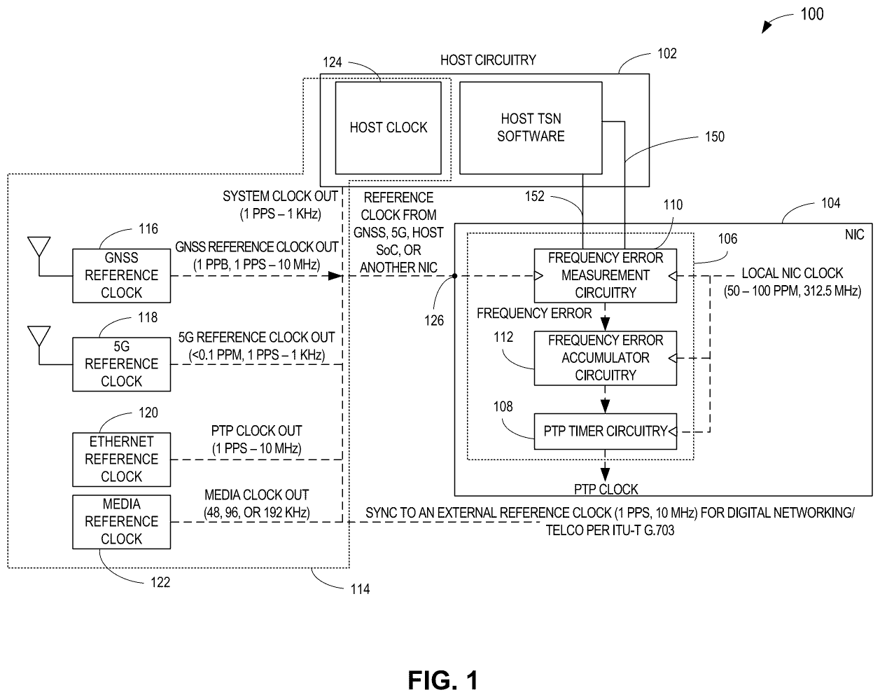

FIG. 1 is a block diagram of example environment 100 in which example syntonization circuitry operates to syntonize timing devices. In the illustrated example of FIG. 1, the environment 100 includes example host circuitry 102, which may be, for example, an Internet-of-Things (IoT) device to perform operations that are coordinated with any number of other devices (e.g., other networked devices, other on-board devices, etc.). In some examples, the host circuitry 102 is a system-on-chip (SoC) device communicatively connected to a network interface controller (NIC) 104. The example NIC 104 includes example syntonization circuitry 106 and example PTP timer circuitry 108. The example syntonization circuitry 106 includes example frequency error measurement circuitry 110 and example frequency error accumulator circuitry 112, described in further detail below.

The illustrated example of FIG. 1 also includes reference clock sources 114. The example reference clock sources 114 include an example global navigation satellite system (GNSS) reference clock 116, an example 5G reference clock 118, an example Ethernet reference clock 120, an example media reference clock 122, and an example host clock 124. In some examples, the reference clock sources 114 are external to the host circuitry 102, internal to the host circuitry 102, external to the NIC 104, and/or internal to the NIC 104. In some examples, the host circuitry 104 includes a frequency lock indicator input 150 to detect instances and/or otherwise obtain information corresponding to a frequency lock achieved by the example frequency error measurement circuitry 110 (e.g., via an IRQ register managed by host TSN software executed by the host circuitry 102). In some examples, the host circuitry 104 includes a frequency error and connected PTP clock input 152 to obtain information corresponding to frequency error information. The example references clocks of the reference clock sources 114 are listed for purposes of example and not limitation. Some examples disclosed herein may not include and/or otherwise use any or some of these types of reference clocks. For instance, wireless networks associated with 5G services may include the 5G reference clock 118 or the GNSS reference clock 116, while other operating environments may include an input from a networked Ethernet reference clock 120. In some examples, the media reference clock 122 associated with streaming services is used as the source to which syntonization efforts should be directed. The example GNSS reference clock 116 produces a timing output having a relatively high precision (less than 0.1 ppm) and an output frequency between 1 Hz to 10 MHz, and may be used in Edge platforms for operations compliant with PTP (e.g., IEEE 1588 standards). Similarly, the example 5G reference clock 118 also exhibits a relatively high precision and may be used in telco operations. While other reference clock sources may exhibit a relatively lower degree of precision, some examples disclosed herein facilitate syntonization between primary clocks (e.g., reference clocks 114) and secondary clocks (e.g., crystal-oscillator-based clocks) to achieve frequency stabilization therebetween. In some use cases, a precise TOD is not important to correct and/or otherwise expected for device-to-device operation, but rather precise syntonization between such devices facilitates correct and/or otherwise expected operation (e.g., streaming services).

In the illustrated example of FIG. 1, the example host clock 124 may be used as a reference clock, or the example Ethernet reference clock 120 may be used as a reference clock for syntonization efforts disclosed herein. Regardless of the type of source reference clock, a reference clock output is received at a clock input 126 of the NIC 104. In some examples, the clock input 126 is a software defined pin (SDP) or other general purpose input/output (GPIO). In some examples, the reference clock provided to the clock input 126 corresponds to digital packet networking and/or telecommunication applications where the external clock is a 1 pulse-per-second (PPS) or 10 MHz rate source defined in a manner consistent with ITU-T G.703 standards.

In operation, and as described in further detail below, the syntonization circuitry 106 relieves the host circuitry 102 (e.g., the CPU and/or other programmable circuitry of the host circuitry 102) of the computational burdens of syntonization. The frequency error measurement circuitry 110 calculates and/or otherwise determines a frequency error measurement value between a local clock (e.g., a local NIC clock that serves as the input to a PTP clock) and the selected reference clock 114. As described above, a local clock of the NIC 104 may utilize crystal-based circuitry that is cost effective, but subject to errors. The example frequency error accumulator circuitry 112 accumulates occurrences (e.g., accumulates phase error values) where phase differences exist between the local clock and the reference clock. During the accumulation of such phase differences, which quantify the magnitude and direction of the frequency error, the example frequency error measurement circuitry adjusts a numerically controlled oscillator (NCO) to adjust the local clock in a manner that aligns with the reference clock. Based on such alignment efforts resulting in satisfaction of a threshold phase difference (e.g., satisfaction of the threshold of an average phase error when a current phase error is lower than the threshold difference value), which suggests frequency alignment between the local clock and the reference clock, the accumulated phase error values (e.g., the accumulated frequency error information) are used by the PTP timer circuitry 108 to adjust the PTP clock. The example syntonization circuitry 106 also provides signaling information for other network nodes (e.g., in both downstream and upstream devices) to mitigate frequency errors due to clock drift across the TSN network. Mitigation efforts enabled by examples disclosed herein may include neighbor network node calculations of neighbor rate ratio (NRR) values to inform such neighbors that frequency adjustment information is available to permit correction of clock frequency errors (e.g., downstream and/or upstream syntonization).

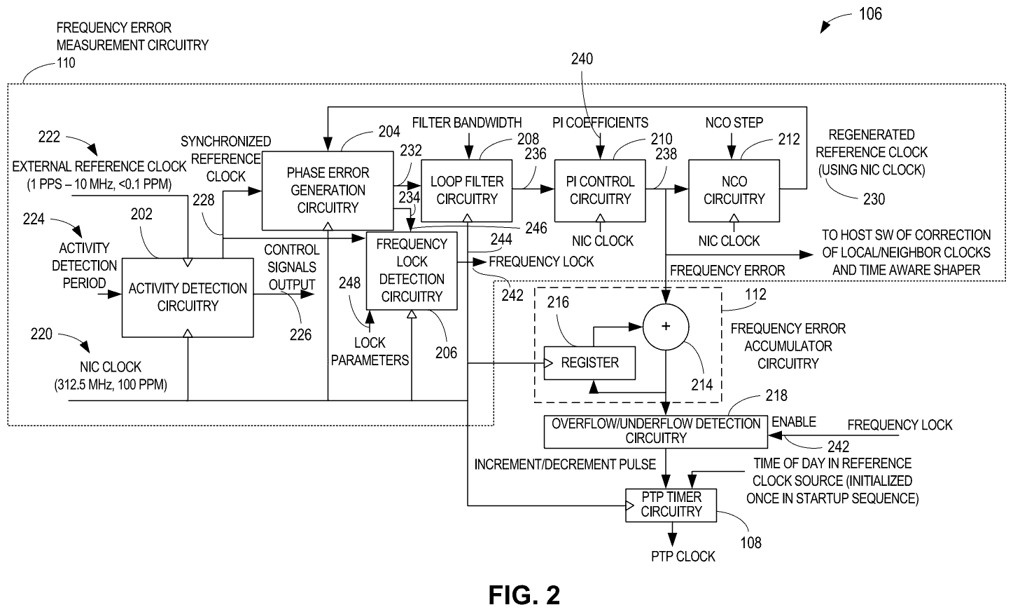

FIG. 2 is a block diagram of an example implementation of the syntonization circuitry 106 of FIG. 1 to syntonize timing devices. In some examples, the syntonization circuitry of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of instructions to perform operations. It should be understood that some or all of the circuitry of FIG. 2 may, thus, be instantiated at the same or different times. Moreover, in some examples, some or all of the circuitry of FIG. 2 may be implemented by microprocessor circuitry (e.g., at least one processor circuit) executing instructions and/or Field Programmable Gate Array (FPGA) circuitry performing operations disclosed herein.

The illustrated example syntonization circuitry 106 of FIG. 2 includes example activity detection circuitry 202, example phase error generation circuitry 204, example frequency lock detection circuitry 206, example loop filter circuitry 208, example proportional/integral (PI) circuitry 210, and example numerically controlled oscillator (NCO) circuitry 212. The example syntonization circuitry 106 of FIG. 2 also includes the example frequency error accumulator circuitry 112, which includes an example adder 214 and an example register 216. The example syntonization circuitry 106 of FIG. 2 also includes example overflow/underflow detection circuitry 218 and the example PTP timer circuitry 108.

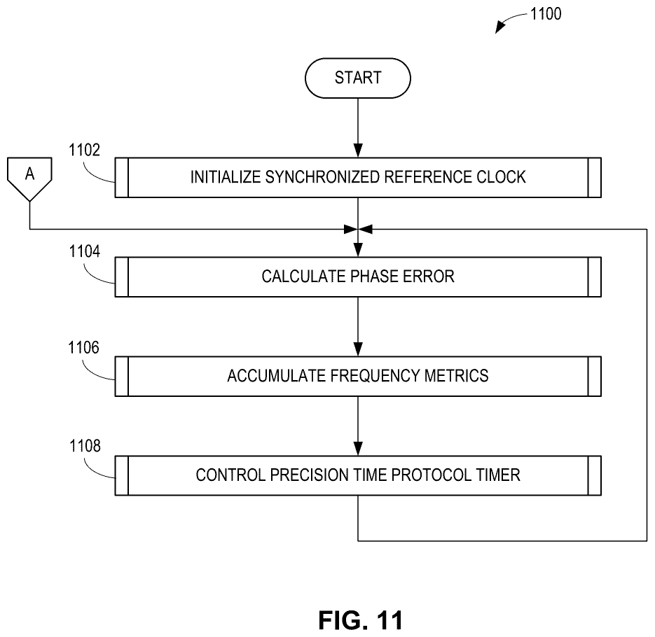

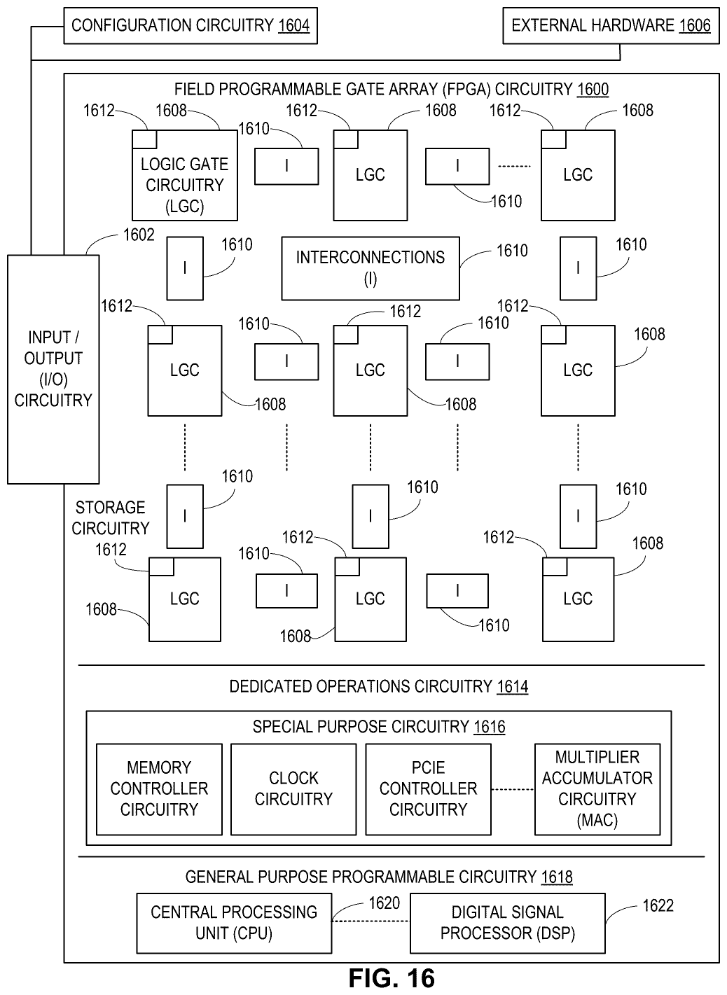

In some examples, the syntonization circuitry includes means for syntonization. For example, the means for syntonization may be implemented by syntonization circuitry 106. In some examples, the syntonization circuitry 106 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the syntonization circuitry 106 may be instantiated by any other combination of hardware, and/or firmware. For example, the syntonization circuitry 106 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for activity detection. For example, the means for activity detection may be implemented by the activity detection circuitry 202. In some examples, the activity detection circuitry 202 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the activity detection circuitry 202 may be instantiated by any other combination of hardware, and/or firmware. For example, the activity detection circuitry 202 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for phase error generation. For example, the means for phase error generation may be implemented by phase error generation circuitry 204. In some examples, the phase error generation circuitry 204 may be instantiated by hardware logic circuitry, which may be implemented by an ASIC, XPU, or FPGA circuitry 1600 of FIG. 16 configured and/or structured to perform operations corresponding FIGS. 11-15. Additionally or alternatively, the phase error generation circuitry 204 may be instantiated by any other combination of hardware, and/or firmware. For example, the phase error generation circuitry 204 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for frequency lock detection. For example, the means for frequency lock detection may be implemented by the frequency lock detection circuitry 206. In some examples, the frequency lock detection circuitry 206 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the frequency lock detection circuitry 206 may be instantiated by any other combination of hardware, and/or firmware. For example, the frequency lock detection circuitry 206 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for filtering. For example, the means for filtering may be implemented by the loop filter circuitry 208. In some examples, the loop filter circuitry 208 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the loop filter circuitry 208 may be instantiated by any other combination of hardware, and/or firmware. For example, the loop filter circuitry 208 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for proportional/integral (PI) control. For example, the means for PI control may be implemented by the PI control circuitry 210. In some examples, the PI control circuitry 210 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the PI control circuitry 210 may be instantiated by any other combination of hardware, and/or firmware. For example, the PI control circuitry 210 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for oscillator control. For example, the means for oscillator control may be implemented by the NCO circuitry 212. In some examples, the NCO circuitry 212 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the NCO circuitry 212 may be instantiated by any other combination of hardware, and/or firmware. For example, the NCO circuitry 212 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for error accumulation. For example, the means for error accumulation may be implemented by the frequency error accumulator circuitry 112. In some examples, the frequency error accumulator circuitry 112 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the frequency error accumulator circuitry 112 may be instantiated by any other combination of hardware, and/or firmware. For example, the frequency error accumulator circuitry 112 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In some examples, the syntonization circuitry includes means for overflow/underflow detection. For example, the means for overflow/underflow detection may be implemented by the overflow/underflow detection circuitry 218. In some examples, the overflow/underflow detection circuitry 218 may be instantiated by hardware logic circuitry, which may be implemented by an ASIC, XPU, or FPGA circuitry 1600 of FIG. 16 configured and/or structured to perform operations corresponding to FIGS. 11-15. Additionally or alternatively, the overflow/underflow detection circuitry 218 may be instantiated by any other combination of hardware, and/or firmware. For example, the overflow/underflow detection circuitry 218 may be implemented by at least one or more hardware circuits (e.g., discrete and/or integrated analog and/or digital circuitry, an FPGA, an ASIC, an XPU, a comparator, an operational-amplifier (op-amp), a logic circuit, etc.) configured and/or structured to perform some or all of the operations corresponding to the flowcharts of FIGS. 11-15 without executing software or firmware, but other structures are likewise appropriate.

In operation, and as a relatively high-level description of the illustrated example of FIG. 2, the syntonization circuitry 106 receives power when its associated platform or hardware assembly receives power, such as when a power switch is activated. The activity detection circuitry 202 initializes a synchronized reference clock, which is based on a local clock (e.g., a local NIC clock running at 312.5 MHz having a relatively poor accuracy of 100 ppm) and a reference clock (e.g., a GNSS clock running at 10 MHz having a good accuracy less than 0.1 ppm). Early stages of operation attempt to generate the synchronized reference clock as close as possible to a phase match between the local clock and the reference clock, but initial phase errors therebetween may not satisfy threshold values indicative of a frequency lock. The phase error generation circuitry 204 calculates such phase error values between the frequencies of a regenerated reference clock and a synchronized reference clock (described in further detail below). The frequency error accumulator circuitry 112 accumulates frequency error value metrics and updates the NCO circuitry 212 to cause corrections in a regenerated reference clock (sometimes referred to herein as a “regenerated clock”). In some examples disclosed herein, phase error values are averaged via the loop filter circuitry 208, and then processed via a PI controller (e.g., the PI control circuitry 210) prior to adjustment of the NCO circuitry 212. The phase error is processed by the PI control circuitry 210 to produce frequency error. In some examples the frequency error (e.g., frequency error information, frequency error values) is propagated across one or more network nodes. After iterative adjustments of the NCO circuitry 212 in view of improved syntonization between the regenerated reference clock and the external reference clock (e.g., relatively lower phase error), the overflow/underflow detection circuitry 218 generates correction pulses as input to the PTP timer circuitry 108 provided a frequency lock has occurred. The correction pulses format and/or otherwise modify the correction pulses for consumption by a PTP clock to cause PTP timer syntonization with the reference clock when a frequency lock trigger occurs. In some examples, the PI control circuitry 210 enables a read-only register for frequency error information and/or correction information to be acquired by nodes of the network. In some examples, the PI control circuitry 210 enables the read-only register to provide and/or otherwise make available the frequency error information after a frequency lock trigger occurs. In effect, the PI control circuitry 210 causes correction of frequency errors of nodes of the network after a frequency lock trigger occurs.

Returning to the example activity detection circuitry 202 of FIG. 2, an internal clock 220 (e.g., a second clock, sometimes referred to as an internal sampling clock) generates a local clock output that is received and/or otherwise retrieved by the activity detection circuitry 202. Additionally, a reference clock 222 (e.g., a first clock) generates a reference clock output that is received and/or otherwise retrieved by the activity detection circuitry 202. Prior to any attempts to synchronize the internal clock 220 with the reference clock 222, the activity detection circuitry monitors for active time input signals from both clocks for an activity detection period 224, which may be a threshold number of cycles. Based on the number of cycles not satisfying a threshold value of the activity detection period 224, a control signal output 226 is driven low (e.g., FALSE). Generally speaking, some examples disclosed herein apply efforts to syntonize timing devices after validating a continuous presence of timing signals, which reflects steady state conditions where clock inputs are consistently received from the local clock 220 and the reference clock 222.

Based on detection of the threshold activity period 224, the control signal output 226 is driven high (e.g., TRUE), and the activity detection circuitry 202 generates an initial synchronized reference clock pulse 228 (e.g., sometimes referred to herein as a “pulse output” or a “synchronized reference clock”) based on the reference clock 222 and the internal clock 220 (e.g., 312.5 MHz) at the same periodicity as the reference clock 222 (e.g., 10 MHz). In some examples, the synchronized reference clock pulse 228 is sampled at a rising edge of the NIC clock 220. Additionally, because syntonization efforts have begun, the control signal output 226 from the activity detection circuitry 202 is available to be read by host TSN software of the example host circuitry 102. In some examples, the host circuitry 102 sets an initial TOD value for the PTP clock (e.g., a third clock) by sending a TOD signal from the reference clock 222 to the PTP timer circuitry 108. Unlike known approaches that attempt to synchronize the TOD with one or more network devices through a relatively high number of reference clock requests and transmissions (e.g., consuming substantial network bandwidth), some examples disclosed herein include a single TOD initialization task. To the extent that further TOD adjustments are needed in network clocks, some examples disclosed herein maintain frequency syntonicity so that clock drift phenomena is reduced in the local clock and/or other clocks within the TSN network.

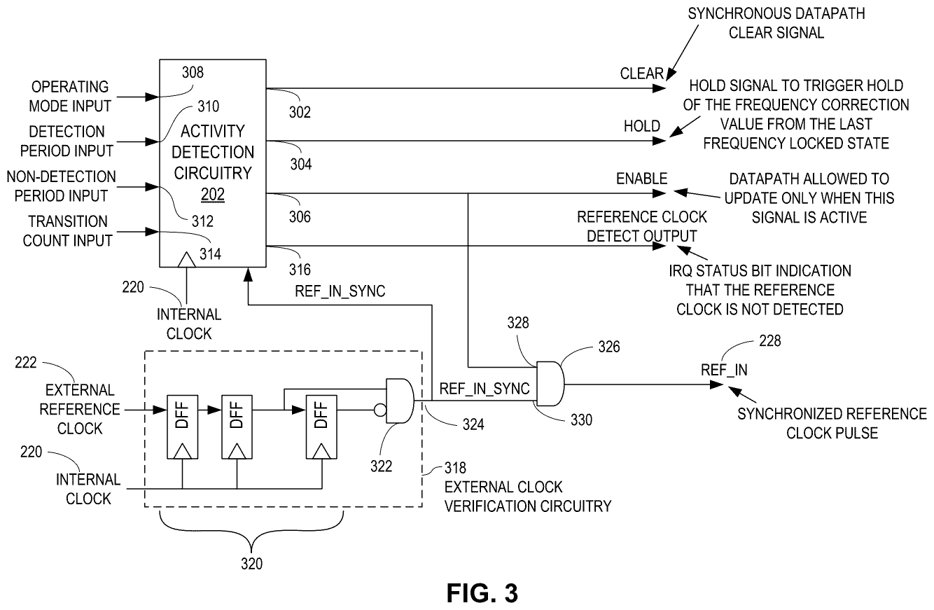

FIG. 3 is a block diagram of additional detail of the activity detection circuitry 202 of FIG. 2. In the illustrated example of FIG. 3, the activity detection circuitry 202 includes a clear control output 302, a hold control output 304, an enable control output 306. In particular, signals from control outputs of the activity detection circuitry 202 set a datapath of the frequency error measurement circuitry 110. The activity detection circuitry 202 also includes an operating mode input 308, a detection period input 310, a non-detection period input 312, and a transition count input 314. The activity detection circuitry 202 also includes a reference clock detect output 316.

In operation, the example activity detection circuitry 202 sets an operating mode of the frequency error measurement circuitry 110 based on the operating mode input 308. Depending on a value the operating mode input 308, the activity detection circuitry 202 generates a clear control signal at the clear control output 302 (e.g., when the operating mode input 308 is set to 00), a hold control signal at the hold control output 304 (e.g., when the operating mode input 308 is set to 10), and an enable control output at the enable control output 306 (e.g., when the operating mode input 308 is set to 01). As described above, the synchronized reference clock pulse 228 is provided to the phase error generation circuitry 204 and generated by synchronizing to the internal clock 220 when the enable control output 306 is true.

When the clear control output 302 is true, the frequency error measurement circuitry 110 causes synchronous clearing of the datapath during an initialization, or if a frequency lock condition is not detected over a threshold period. In some examples, an external signal (e.g., from the host circuitry 102) may be received by the activity detection circuitry 202 to cause the clear control output 302 to be asserted (e.g., to cause an initialization of the frequency error measurement circuitry 110).

Prior to the activity detection circuitry 202 asserting the enable control output 306 as true, the presence of the external reference clock 222 is verified for a programmed period while the operating mode input 308 is enabled (e.g., value 01). In particular, the illustrated example of FIG. 3 includes external clock verification circuitry 318 including a series of cascaded flip-flops 320 to verify a stable presence of the external reference clock 222. The external clock verification circuitry 318 includes a first logic gate 322 coupled to the cascaded flip-flops, and an output 324 to provide a binary status indicator corresponding to the presence of a stable external reference clock. The detection period input 310 receives a value indicative of an active detection period that, if true, validates the presence of a stable external reference clock 222. An example second logic gate 326 includes a first input 328 coupled to the enable control output 306 and a second input 330 coupled to the output 324 of the external clock verification circuitry 318. When both inputs of the second logic gate 326 are true and a threshold number of reference clock input pulses occur over a threshold number of cycles of the internal clock 220, the activity detection circuitry 202 provides a synchronized reference clock pulse 228. As described above, the synchronized reference clock pulse 228 is provided as an input to the phase error generation circuitry 204.

The example activity detection circuitry 202 asserts the hold control output 304 in response to a corresponding hold input value (e.g., 10) at the operating mode input 308. The hold signal causes a frequency correction value from a prior lock event to be held and/or otherwise maintained in the frequency error measurement circuitry 110. In some examples, the hold signal is triggered by the activity detection circuitry 202 in response to an external input to the operating mode input 308 and/or if the external reference clock 222 is missing for a programmed period of time set by the example non-detection period input 312.

The example reference clock detect output 316 is asserted by the activity detection circuitry 202 when the external reference clock is absent and/or otherwise missing for a period of time defined by the detection period input 310. In some examples, the reference clock detect output 316 is provided and/or otherwise available to external interrupt request status bit inputs that may monitor the frequency error measurement circuitry 110.

The example phase error generation circuitry 204 calculates phase error values based on a phase difference between the synchronized reference clock pulse 228 and a regenerated reference clock 230. As described in further detail below, the regenerated reference clock 230 is based on a phase locked loop (PLL) architecture to allow the regenerated reference clock to mimic the reference clock 222. The example phase error generation circuitry 204 generates two separate outputs. A first output 232 reflects a phase error sign (e.g., −1, 0, +1, referred to as phase error direction indicators), and a second output 234 reflects a phase error value (e.g., in nSec). In some examples, the second output 234 is referred to as an accumulated phase error 234. The phase error value of the second output 234 represents a relatively high time resolution granularity because the phase error is measured by the phase error generation circuitry 204 in units of cycles of a period of the internal clock 220 (e.g., a 3.2 nSec period corresponding to an internal clock 220 rate of 312.5 MHz). The first output 232 of phase error direction indicators is a two-bit signal having values of negative one (−1), zero (0), or one (+1) depending on whether the reference clock 222 is lagging the regenerated reference clock, neither lagging nor leading the regenerated reference clock (e.g., “phase aligned”), or leading the regenerated reference clock, respectively. In some examples, the first output 232 is referred to as a raw phase error output 232. If the phase error generation circuitry 204 detects the reference clock 222 is lagging the regenerated clock 230, then it generates a series of −1 pulses. Alternatively, if the phase error generation circuitry 204 detects the reference clock 222 has no phase error (e.g., a threshold phase error value, phase aligned such as a small phase error), the phase error generation circuitry 204 generates a series of 0 pulses. If the phase error generation circuitry 204 detects the reference clock 222 has a leading phase error, then the phase error generation circuitry 204 generates a series of +1 pulses.

Phase error leading and lagging phenomena are expected to occur after initialization of the example syntonization circuitry 106 framework because the regenerated reference clock 230 is supplied from a numerically controlled oscillator (NCO) that is executing at a rate set by the local clock 230 (e.g., a NIC clock rate of 312.5 MHz). Because the local clock is typically utilizing crystal-oscillators rather than relatively more expensive atomic-level timing circuitry, the regenerated reference clock 230 will initially reflect frequency offsets (errors) relative to the reference clock 222. However, these frequency offsets improve after iterative cycles of the syntonization circuitry 106 based on adjustments caused by the example NCO circuitry 212. Phase offsets between the reference clock 222 and the regenerated reference clock 230 are mitigated (e.g., reduced) when they are time aligned at startup.

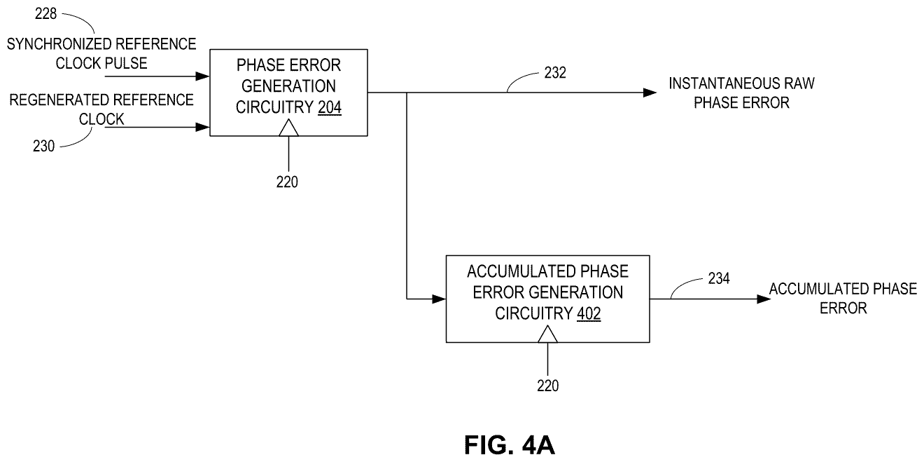

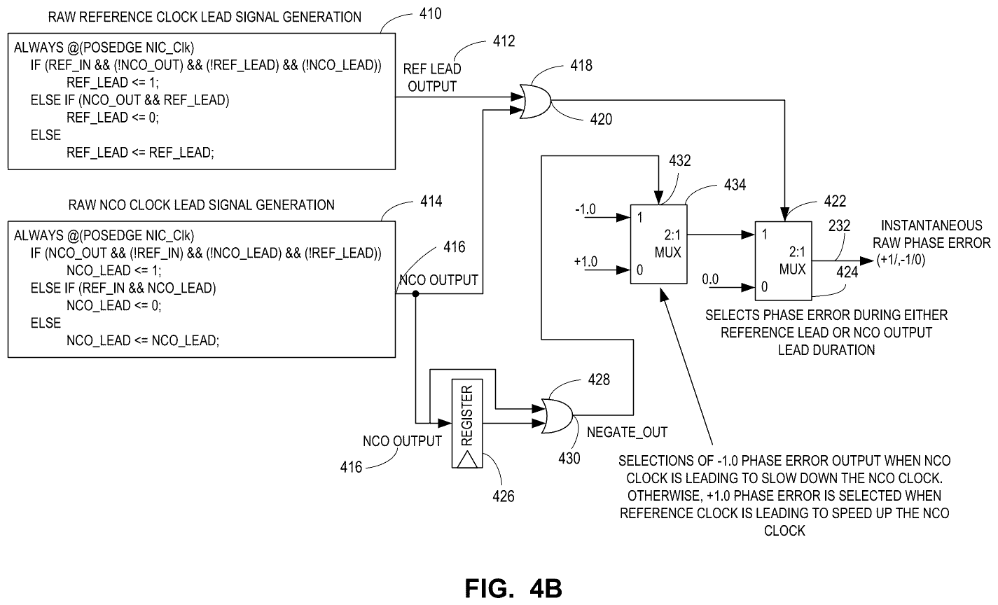

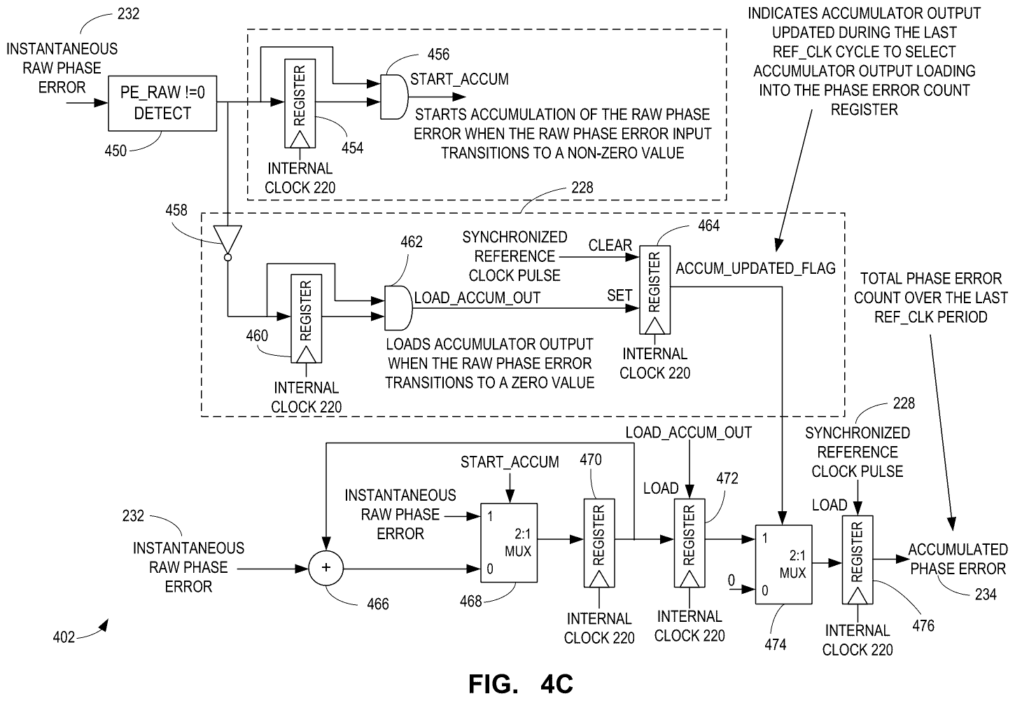

FIG. 4A is a block diagram of additional detail of the phase error generation circuitry 204 of FIG. 2. In the illustrated example of FIG. 4A, the phase error generation circuitry 204 receives the synchronized reference clock pulse 228 and the regenerated reference clock 230. The phase error generation circuitry 204 compares the synchronized reference clock pulse 228 to the internally regenerated reference clock 230 (from the NCO circuitry 212) to generate a raw phase error output 232 (of phase error direction indicators). As described above, the raw phase error output 232 is a two-bit raw phase error output to reflect an instantaneous phase error as +1, −1, or 0. The raw phase error output 232 is fed to the example loop filter circuitry 208 where the instantaneous phase error values are smoothed (e.g., lowpass filtered) and processed by the PI control circuitry 210 prior to causing adjustments to the NCO circuitry 212.

The raw phase error output 232 is also fed to example accumulated phase error generation circuitry 402 to generate the accumulated phase error 234 that was detected in a prior clock period of the external reference clock 222. In some examples, the accumulated phase error 234 is a signed (e.g., 19-bit) accumulated phase error in units of a NIC clock cycle. The phase error 234 is consumed by the example frequency lock detection circuitry 206 to generate a frequency lock enable signal 242.

FIG. 4B is a block diagram of additional detail of the phase error generation circuitry 204 of FIG. 4A. In the illustrated example of FIG. 4B, a first register transfer level (RTL) circuit 410 detects circumstances where the external reference clock 222 leads the regenerated reference clock 230 to generate a logic high value at a reference lead output 412. On the other hand, a second RTL circuit 414 detects circumstances where the regenerated reference clock 230 leads the external reference clock 222 to generate a logic high value at an NCO output 416. The example reference lead output 412 and the example NCO output 416 are coupled to a first logic gate (NOR) 418. The first logic gate 418 includes a first output 420 coupled to an input 422 of a first multiplexer (MUX) 424. The NCO output 416 is also coupled to a first register 426 and a second logic gate 428. A second output 430 of the second logic gate 428 is coupled to an input 432 is coupled to a second MUX 434.

In operation, when the external reference clock 222 leads the regenerated reference clock 230, the first MUX 424 generates a +1 output. As described above and in further detail below, the +1 output causes a frequency increase of the NCO circuitry 212. When the regenerated reference clock 230 leads the external reference clock 222, the first MUX 424 generates a −1 output. As described above and in further detail below, the −1 output causes a frequency decrease of the NCO circuitry 212. However, when no lead occurs, the example first MUX 424 generates a 0 output, which prevents frequency changes to the NCO circuitry 212.

FIG. 4C is a block diagram of additional detail of the accumulated phase error generation circuitry 402 of FIG. 4A. The illustrated example of FIG. 4C includes raw phase detection circuitry 452, a first register 454, a first logic gate 456, a second logic gate 458, a second register 460, a third logic gate 462, a third register 464, an adder 466, a first MUX 468, a fourth register 470, a fifth register 472, a second MUX 474, and a sixth register 476. In operation, the example raw phase detection circuitry 452 detects a non-zero raw phase error condition and outputs a logic true (e.g., high) when the raw phase error is non-zero. In such circumstances, a non-zero phase error is indicative of an active phase error between the synchronized reference clock 228 and the regenerated reference clock 230.

The example first register 454 and first logic gate 456 detect transitions to a non-zero value (e.g., −1 or +1) (e.g., indicative of phase error) from a zero value (e.g., indicative of no phase error). The example first logic gate 456 generates a logic high output as a “start_accum” pulse signal to start a phase error accumulation by initializing the first MUX 468 with a current value of the instantaneous raw phase error 232. The example second logic gate 458, second register 460, third logic gate 462, and third register detect transitions from a non-zero value (e.g., −1 or +1) to a zero value and generate a logic high output as a “load_accum_out” pulse signal. The “load_accum_out” pulse signal causes the accumulator output to be loaded at the end of a phase error accumulation for a current reference clock cycle. Additionally, the “load_accum_out” pulse signal causes an “accum_updated_flag” register to be set, which indicates an accumulator output was updated during a previous reference clock cycle. In some examples, the “accum_updated_flag” register remains set until the synchronized reference clock pulse 228 clears this flag register after loading during a rising edge pulse of the external reference clock.

The example loop filter circuitry 208 processes strings of the first output 232 of signed pulse values (−1, 0, or +1) during each clock period. The loop filter circuitry 208 operates as a low pass filter to smooth incoming samples to prevent overcorrection behaviors when controlling the NCO of the NCO circuitry 212. Additionally, the loop filter circuitry 208 mitigates and/or otherwise attenuates jitter effects and phase noise that may occur in the reference clock 222 as part of a closed loop PLL frequency response. In some examples, a transfer function of a first order infinite impulse response (IIR) is applied to the loop filter circuitry 208 in a manner consistent with example Equation 1.

$$H ( z ) = \frac{∝ * {z}^{- 1}}{( 1 - ( 1 - ∝ ) * {z}^{- 1} )} . \qquad Equation 1$$

In the illustrated example of Equation 1, alpha (a) reflects a programmable value to define a lowpass filter bandwidth.

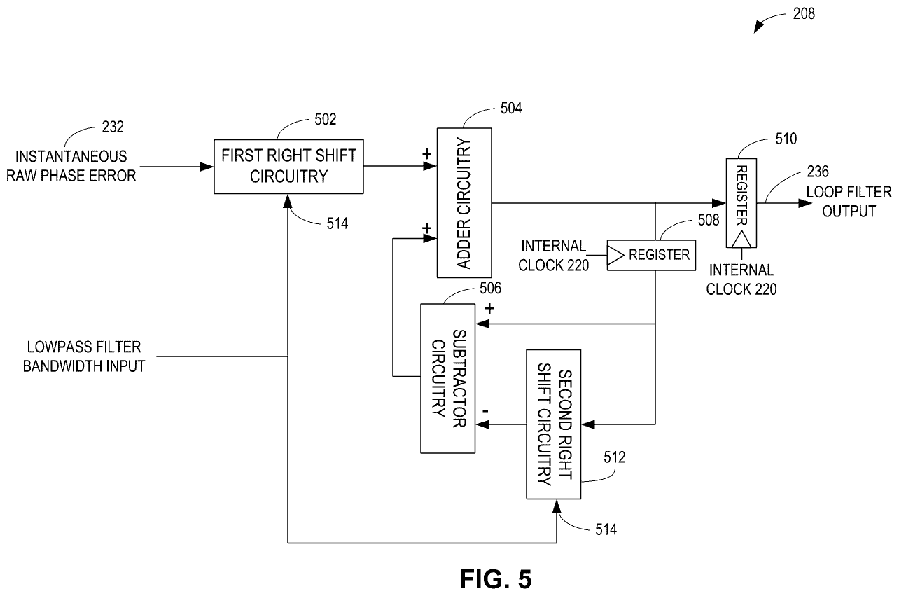

FIG. 5 is a block diagram of additional detail of the loop filter circuitry 208 of FIG. 2. In the illustrated example of FIG. 5, the loop filter circuitry 208 includes first right shift circuitry 502, adder circuitry 504, subtractor circuitry 506, a first register 508, a second register 510, and second right shift circuitry 512. In operation, the example loop filter circuitry 208 operates as a single pole IIR lowpass filter with a programmable filter bandwidth (e.g., a −3 dB cutoff frequency).

The first right shift circuitry 502 receives an input of the instantaneous raw phase error 232 (e.g., −1, 0, +1). The example loop filter circuitry 208 of FIG. 5 smooths the incoming pulsed signals to prevent larger phase correction steps being applied at the NCO circuitry 212, which improves loop stability and closed loop tracking performance. Additionally, the example loop filter circuitry 208 of FIG. 5 attenuates cycle-to-cycle jitter and phase noise that may occur in the synchronized reference clock pulse 228 via the closed loop PLL frequency response. The example first right shift circuitry 502 and the example second right shift circuitry 512 include bandwidth inputs 514 to receive a value to define the lowpass filter bandwidth.

The example PI control circuitry 210 generates phase and frequency correction signals at a PI output 238 that are based on an output 236 of the loop filter circuitry 208. In particular, the PI control circuitry 210 applies coefficient inputs 240 as a proportional coefficient (Kₚ) and an integral coefficient (Kᵢ) to a z-domain transfer function in a manner consistent with example Equation 2.

$$H ( z ) = {K}_{p} + {K}_{i} * ( \frac{{z}^{- 1}}{( 1 - {z}^{- 1} )} ) . \qquad Equation 2$$

The phase and frequency correction signals at the PI output 238 may be considered a type of frequency error signal (e.g., a correction value or bias value) to control correction of a numerically controlled oscillator (NCO) of the NCO circuitry 212. The error reflects the frequency error between the reference clock 222 and the local clock 220, but the NCO circuitry output 230 (the regenerated reference clock) iteratively algins to the frequency of the reference clock 222. Stated differently, the example correction values of at the PI output 238 of the PI control circuitry 210 tunes the NCO, which is effectively a phase accumulator that uses the local clock 220 to generate a clock pulse (the regenerated reference clock 230) as close as possible to the same rate as the reference clock 222. The PI control circuitry 210 biases (e.g., injects bias to) the NCO circuitry 212 to cause the NCO to either speed up or slow down depending on whether there is a positive or negative frequency error (lead/lag). As a result, input bias to cause the NCO to speed up or slow down causes modification of the regenerated reference clock. However, while initial operation of the syntonization circuitry 106 will exhibit phase and frequency errors between these clocks, those errors diminish over iterative corrections of a phase-locked-loop (PLL) of the phase error generation circuitry 204, the loop filter circuitry 208, the PI control circuitry 210, and the NCO circuitry 212.

Because the PI control circuitry 210 generates frequency error values (e.g., correction values) at the PI output 238, some examples disclosed herein accumulate ones of those frequency error values to determine a correction value for the PTP timer circuitry 108. However, the correction value of accumulated ones of frequency error values is not provided to the PTP timer circuitry until after a threshold phase error between the regenerated reference clock 230 and the reference clock 222 is achieved.

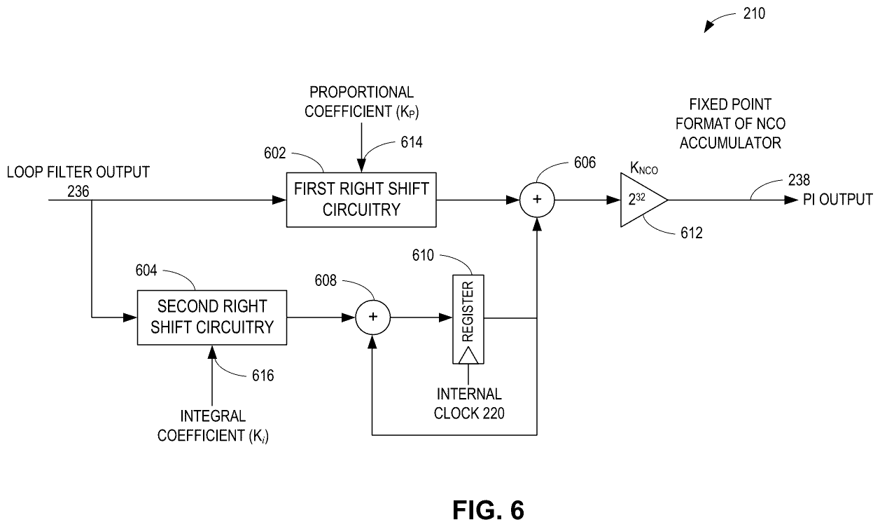

FIG. 6 is a block diagram of additional detail of the PI control circuitry 210 of FIG. 2. In the illustrated example of FIG. 6, the PI control circuitry 210 includes first right shift circuitry 602, second right shift circuitry 604, first adder circuitry 606, second adder circuitry 608, a register 610, and left shift circuitry 612 (sometimes referred to as gain circuitry). The example first right shift circuitry 602 includes a proportional coefficient input 614, and the second right shift circuitry 604 includes an integral coefficient input 616.

In operation, the PI control circuitry 210 applies PI control coefficients, such as a proportional coefficient (Kₚ) at the proportional coefficient input 614, and an integral coefficient (Kᵢ) at the integral coefficient input 616. The applied PI control coefficients cause phase and frequency correction of the NCO circuitry 212 by scaling the loop filter output by Kₚ and Kᵢ, respectively. As described above, in some examples the PI control circuitry 210 applies a z-domain transfer function in a manner consistent with example Equation 2. In some examples, the PI control coefficients are set by the PI control circuitry 210 in a manner consistent with example Equation 3.

$${K}_{i} = \frac{{K}_{p}^{2}}{4} . \qquad Equation 3$$

An example PI output 238 is the result of a gain factor (K_{NCO}) (e.g., 2³²) applied by the example gain circuitry 612.

Returning to the illustrated example of FIG. 2, the example adder 214 of the frequency error accumulator circuitry 112 accumulates error values from the PI output 238 and stores those error values in the register 216. The error values represent overflow and/or underflow conditions, which are provided to the overflow/underflow detection circuitry 218. The overflow/underflow detection circuitry 218 analyzes the error values to generate either an increment or a decrement pulse, which is not transmitted, and/or otherwise provided to the PTP timer circuitry 108 until an enable signal is asserted as the frequency lock enable signal 242 (e.g., the PTP timer circuitry 108 retrieves, receives and/or otherwise obtains a frequency lock trigger from the frequency lock detection circuitry 206 based on satisfaction of the phase error threshold). When the frequency lock condition is triggered, enabled, determined, and/or otherwise asserted, and as described in further detail below, the increment or decrement pulse allows for gradual changes in the PTP timer due to frequency errors while maintaining linear time and avoiding drastic changes (e.g., jitter). Additionally, frequency errors of the PI output 238 are also transmitted and/or otherwise provided to the host circuitry 102 and/or other time sensitive networking (TSN) systems (e.g., software) to serve as correction values that enable correction of clocks and configuration of time aware shaper efforts. In some examples, the frequency errors of the PI output 238 are communicated to neighbor networked devices to inform them that they may exhibit errors in need of correction. For instance, the example syntonization circuitry 106 may be considered a primary device deemed to exhibit an accurate frequency value, while network accessible neighbor devices (e.g., having relatively less expensive crystal oscillators, 100 ppm) are considered secondary devices that do not have the benefit of a reference clock with superior accuracy capabilities (e.g., the reference clock 222, <0.1 ppm). As such, in the event of reported frequency errors, the neighboring secondary devices defer to the increment/decrement pulse information provided by the primary device.

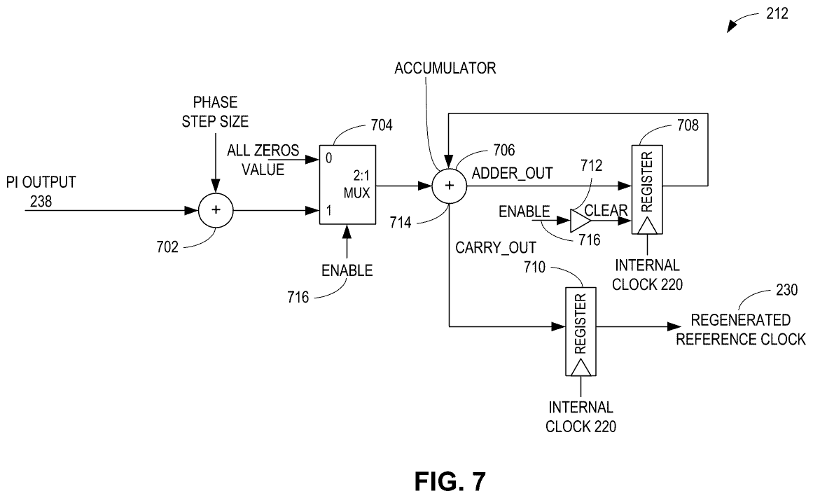

FIG. 7 is a block diagram of additional detail of the NCO circuitry 212 of FIG. 2. In the illustrated example of FIG. 7, the NCO circuitry 212 includes a first adder 702 (sometimes referred to as a phase accumulator), a MUX 704, a second adder 706 (sometimes referred to as an accumulator), a first register 708, a second register 710, and a buffer 712. In operation, the example NCO circuitry 212 receives the PI output 238 as a frequency error correction word. The phase accumulator 702 applies a phase step size set in a manner consistent with example Equation 4.

$$Phase Step Size = \frac{{2}^{32}}{( \frac{Internal Clock Freq}{Reference Clock Freq} )} . \qquad Equation 4$$

In the illustrated example of Equation 4, the internal clock frequency corresponds to, for example, the frequency of the NIC 104 (e.g., 312.5 MHz) and the reference clock frequency corresponds to the frequency of the external clock. The numerator 2³² indicates the modulo count of the accumulator 706 after which its output wraps around to generate a carry_out output 714 for one NIC clock cycle. The denominator of example Equation 4 corresponds to an oversampling ratio of the NIC's internal clock frequency relative to the external reference clock. To illustrate, if the internal NIC clock frequency is 312.5 MHz and the reference clock is 10 MHz, the corresponding phase step size is 13743.895 (=2³²/(312.5e6/1e3)).

Based on the phase step size, the rate at which the carry_out 714 is generated from the accumulator 706 will effectively be at the same frequency as the reference clock when the PI output 238 is zero. However, when there is a non-zero PI output 238, the signed frequency error word speeds up or slows down the accumulator 706 so that the phase error between these two clocks is gradually driven to a steady state zero over time. The regenerated reference clock 230 from the example second register 710 is fed back to the phase error generation circuitry 204, as described above.

The example MUX 704 and the first register 708 include an enable input 716. As described above, the example activity detection circuitry 202 enables the operation of the NCO circuitry 212 when asserted. However, when the enable input 716 is de-asserted, the accumulator 706 is held in a cleared state. The enable signal is synchronously asserted by the activity detection circuitry 202 in response to time alignment to the internally synchronized reference clock signal to ensure that any fixed phase offset is minimized when the NCO circuitry 212 is initially enabled (e.g., at startup of a corresponding platform, SoC, etc.).

Returning to the illustrated example of FIG. 2, the source of the frequency lock enable signal 242 is from a frequency enable output 244 of the frequency lock detection circuitry 206. The frequency lock detection circuitry 206 also includes a phase error threshold input 246 that is communicatively connected to the second output 234 of the phase error generation circuitry 204. The frequency lock detection circuitry 206 also includes a lock parameters input 248 to provide a lock threshold value. The frequency lock detection circuitry 206 averages the phase error prior to comparison to the lock threshold value. The lock threshold value may be represented as a phase error value (e.g., in nSec) that, when satisfied (e.g., the phase error threshold input 246 is lower than the lock threshold value corresponding to the lock parameters input 248), causes frequency enable output 244 of the frequency lock detection circuitry 206 to be asserted (e.g., logic “HIGH” or “TRUE”). In other words, this designates a frequency lock condition indicative of a relatively low phase error defined by the lock threshold value.

The asserted frequency enable output 244 received by the frequency lock enable signal 242 of the overflow/underflow detection circuitry 218 causes the increment/decrement pulse to be provided to the PTP timer circuitry 108, thereby allowing correction of one or more PTP clocks (or other clocks) communicatively connected thereto (e.g., secondary devices in a TSN). The frequency lock condition may also cause host software to update other clocks, time aware shapers, and neighbor rate ratio calculations to identify characteristic differences of neighboring clock performance. In some examples, the PTP timer circuitry 108 provides an updated TOD value from the reference clock 222 in response to assertion of the frequency lock 244. As described above, the TOD value may be obtained from a GNSS reference clock, a 5G clock, or some other clock source.

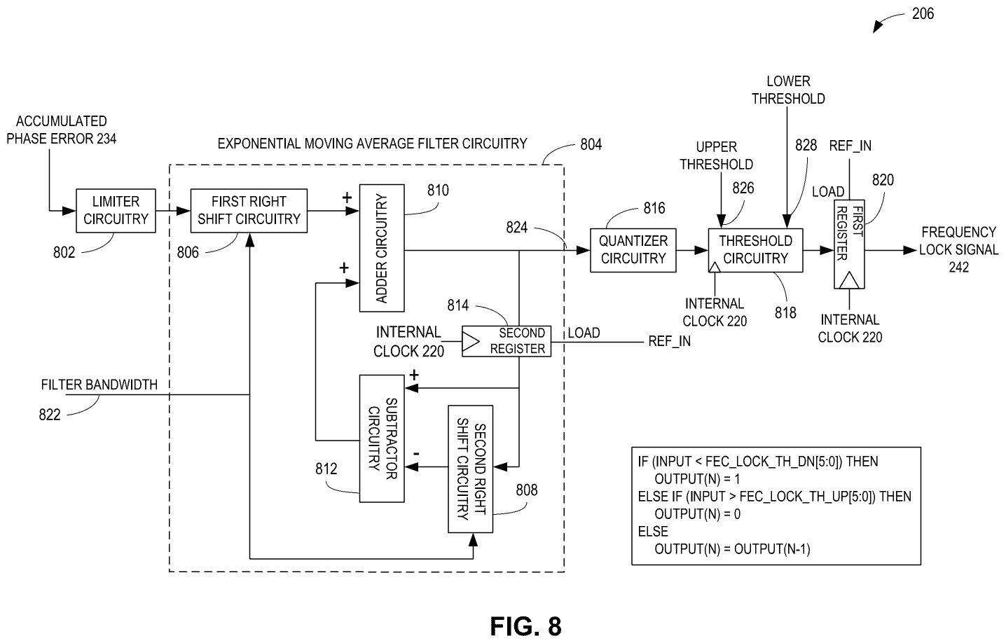

FIG. 8 is a block diagram of additional detail of the frequency lock detection circuitry 206 of FIG. 2. In the illustrated example of FIG. 8, the frequency lock detection circuitry 206 includes limiter circuitry 802, exponential moving average filter circuitry 804, quantizer circuitry 816, thresholding circuitry 818, and a first register 820. The example exponential moving average filter circuitry 804 includes first right shift circuitry 806, second right shift circuitry 808, adder circuitry 810, subtractor circuitry 812 and a second register 814.

In operation, the limiter circuitry 802 of the frequency lock detection circuitry 206 limits the accumulated phase error 234 count value to a relatively lower bit value (e.g., an original 19-bit signed error count value to a 5-bit signed value). In some examples, the magnitude of the limit effect is based on one or more dynamic range tests/evaluations against expected performance. The exponential moving average filter circuitry 804 filters based on a filter bandwidth value at a filter bandwidth input 822. In some examples, the example transfer function of example Equation 1 is used by the exponential moving average filter circuitry 804, in which a filtered output 824 is quantized by the quantizer circuitry 816 (e.g., to 8-bits). The thresholding circuitry 818 compares the quantized value with an upper threshold value at an upper threshold input 826 and a lower threshold value at a lower threshold input 828.

The first register 820 asserts a frequency lock signal (e.g., logic high, true, 1) when a magnitude of the filtered phase error falls below the lower threshold value. On the other hand, the first register 820 de-asserts the frequency lock signal (e.g., logic low, false, 0) when the magnitude of the filtered phase error exceeds the upper threshold value. During periods where the filtered phase error value is between the lower threshold value and the upper threshold value, the first register 820 holds its previous state. In some examples, the frequency lock signal 242 is available to external software applications to enable interrupt actions on transitions (e.g., rising edge transitions, falling edge transitions). In some examples, the first register 820 holds the frequency lock signal 242 value as a read-only register bit.

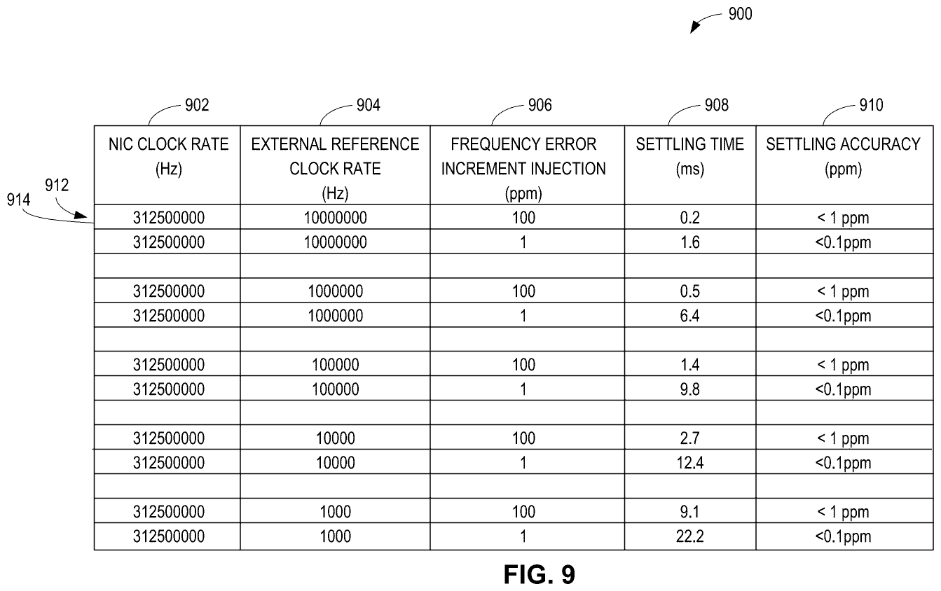

In some examples disclosed herein, settling times associated with achieving particular settling accuracy values (in ppm) are improved. FIG. 9 is a table 900 of example settling times corresponding to different reference clock rates. In the illustrated example of FIG. 9, the table includes a NIC clock rate column 902, an external reference clock rate column 904, a frequency error increment injection column 906, a settling time column 908, and a settling accuracy column 910. The example NIC clock rate column 902 includes values in Hertz (Hz) and reflects frequency values associated with a local clock, such as the example local clock 220 of FIG. 2. The example external reference clock rate column 904 includes values in Hz and reflects frequency values associated with an external reference clock, such as the example reference clock 222 of FIG. 2. The example frequency error increment injection column 906 includes values in ppm and reflects a simulated current operational error of the example syntonization circuitry 106. For instance, a first row 912 of the table 900 reflects a frequency error of 100 ppm, which is indicative of conditions shortly after initialization of the example syntonization circuitry 106 when phase error between a reference clock and local clock are expected to be relatively high. The first row 912 also indicates a reference clock rate of 10 MHz. The example settling accuracy column 910 establishes a target accuracy of less than one part-per-million (ppm), in which some examples disclosed herein accomplish with a settling time of 0.2 milliseconds (ms), as shown in the settling time column 908 of the first row 912. In some examples, the syntonization circuitry 106 is referred to as operating in a “startup mode” after initial operation.

However, as conditions improve, shown in a second row 914 of the example table 900 where the frequency error increment is at a relatively lower value of 1 ppm, settling times of 1.6 mSec occur with a target settling accuracy of less than 0.1 ppm. Stated differently, despite the example conditions of the second row 914 starting out with a substantially lower frequency error increment value (e.g., 1 ppm) as compared to the first row 912 (e.g., 100 ppm), because the target settling accuracy is also substantially lower (e.g., more accurate), a relatively longer settling time results (e.g., 1.6 mSec). In some examples, the syntonization circuitry 106 is referred to as operating in a “track mode” when error conditions are relatively lower, such as conditions represented in the second row 914. The example settling times of the settling time column 908 of FIG. 3 are a function of phase error measurements between the reference clock and the NCO clock being iterated in units of the relatively faster local clock (e.g., 312.5 MHz local clock). Generally speaking, crystals associated with the local clock (e.g., relatively less accurate and less expensive circuitry) fluctuate at approximately 1 to 2 ppm per second based on temperature and voltage effects.

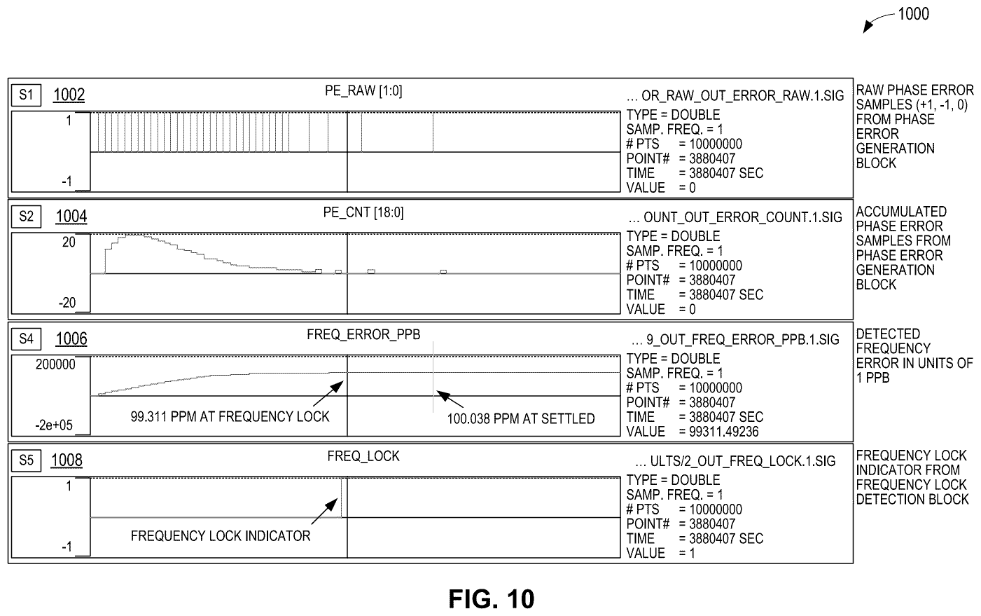

FIG. 10 illustrates example waveforms 1000 of simulated tracking behavior of the example syntonization circuitry 106. In particular, the waveforms 1000 represent a frequency error increment of 100 ppm (between the reference clock and a local clock, such as an internal NIC clock) at initial operation of the syntonization circuitry 106, with time increasing from left-to-right on an x-axis. In the illustrated example of FIG. 10, the waveforms 1000 include a raw phase error waveform 1002 (see S1), an accumulated phase error count waveform 1004 (see S2), a frequency error waveform 1006 (see S4) in parts per billion, and a frequency lock status indicator waveform 1008 (see S5). The example accumulated phase error count waveform 1004 reflects phase error in units of clock cycles of the local clock (e.g., the NIC clock), thus a value of 20 in the y-axis represents 20 clock cycles of the local clock running at, for example 312.5 MHz. The example raw phase error waveform 1002 reflects instances where the example phase error generation circuitry 204 detects a phase error condition, which is the first output 232 having +1 values in this example.

As shown by the example raw phase error waveform 1002, during initial operation of the syntonization circuitry 106 the count of phase error instances is relatively high and, as such, the accumulated phase error count waveform 1004 represents a similarly high accumulation. Such relatively high occurrences of phase error are expected during initialization because the PLL has not yet performed enough iterations to align the frequency of the regenerated reference clock signal 230 with the reference clock 222. The accumulated phase error (1004) gradually settles to zero over time, and when a threshold phase error is achieved, a frequency lock is asserted. In the illustrated example of FIG. 10, at frequency lock the frequency error settles to an error of 99.311 ppm (e.g., a less-than 1 ppm residual error at the frequency lock). When fully settled (e.g., no phase error is detected), the frequency error settles to 100.038 ppm.

While an example manner of implementing the syntonization circuitry of FIG. 1 is illustrated in FIGS. 2, 3, 4A-4C, and 5-8, one or more of the elements, processes, and/or devices illustrated in FIGS. 2, 3, 4A-4C, and 5-8 may be combined, divided, re-arranged, omitted, eliminated, and/or implemented in any other way. Further, the example host circuitry 102, the example NIC 104, the example PTP timer circuitry 108, the example frequency error measurement circuitry 110, the example frequency error accumulator circuitry 112, the example activity detection circuitry 202, the example phase error generation circuitry 204, the example frequency lock detection circuitry 206, the example loop filter circuitry 208, the example PI control circuitry 210, the example NCO circuitry 212, the example adder 214, the example register 216, the example overflow/underflow detection circuitry 218, and/or, more generally, the example syntonization circuitry 106 of FIG. 2, may be implemented by hardware and/or firmware. Thus, for example, any of the example host circuitry 102, the example NIC 104, the example PTP timer circuitry 108, the example frequency error measurement circuitry 110, the example frequency error accumulator circuitry 112, the example activity detection circuitry 202, the example phase error generation circuitry 204, the example frequency lock detection circuitry 206, the example loop filter circuitry 208, the example PI control circuitry 210, the example NCO circuitry 212, the example adder 214, the example register 216, the example overflow/underflow detection circuitry 218, and/or, more generally, the example syntonization circuitry, could be implemented by programmable circuitry, analog circuit(s), digital circuit(s), logic circuit(s), programmable processor(s), programmable microcontroller(s), ASIC(s), programmable logic device(s) (PLD(s)), and/or field programmable logic device(s) (FPLD(s)) such as FPGAs. Further still, the example syntonization circuitry 106 of FIG. 2 may include one or more elements, processes, and/or devices in addition to, or instead of, those illustrated in FIGS. 2, 3, 4A-4C, and 5-8, and/or may include more than one of any or all of the illustrated elements, processes and devices.

Flowchart(s) representative of example operations, which may be implemented and/or instantiated by the syntonization circuitry of FIG. 2 and/or representative of example operations which may be performed by the example programmable circuitry (e.g., an FPGA) discussed below in connection with FIG. 16. In some examples, the operations cause a task, etc., to be carried out and/or performed in an automated manner in the real world. As used herein, “automated” means without human involvement.

Although the example operations are described with reference to the flowchart(s) illustrated in FIGS. 11-15, many other methods of implementing the example syntonization circuitry 106 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware.

FIG. 11 is a flowchart representative of example operations 1100 that may be instantiated, and/or performed by programmable circuitry to syntonize timing devices. The example operations 1100 of FIG. 11 begin at block 1102, at which the activity detection circuitry 202 initializes a synchronized reference clock. In some examples, the synchronized reference clock and the regenerated reference clock are initialized to start-up phase aligned for frequency tracking. The example phase error generation circuitry 204 calculates a phase error (block 1104), and the example frequency error accumulator circuitry 112 accumulates frequency metrics (block 1106). The example syntonization circuitry 106 controls one or more precision time protocol (PTP) timer(s) (block 1108), as described above and in further detail below.

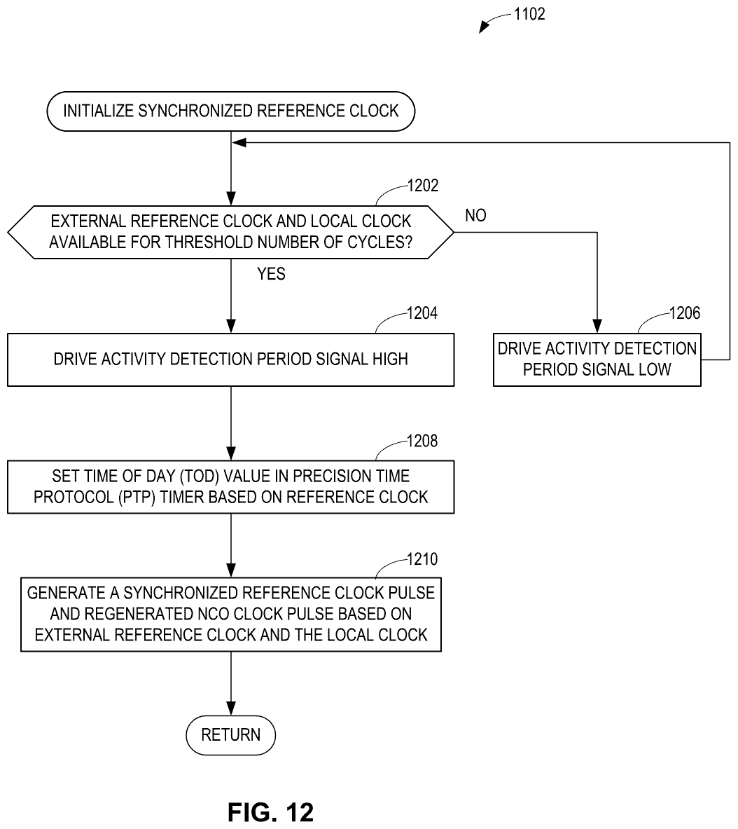

FIG. 12 is a flowchart illustrating additional detail of initializing a synchronized reference clock of block 1102. In the illustrated example of FIG. 12, the activity detection circuitry 202 determines an availability or presence of a reference clock (e.g., an external reference clock, an internal reference clock) and a local clock (e.g., a NIC clock) for a threshold number of cycles (block 1202). As described above, efforts to syntonize clocks is frustrated if such clocks are inconsistently available and/or otherwise intermittent. As such, the activity detection circuitry 202 prevents wasteful efforts to syntonize unless (a) signals from both clocks are available (b) for a threshold number of cycles. In other words, the threshold number of cycles indicates steady state operation of the clocks.

If such conditions are not met, the example activity detection circuitry 202 drives an activity detection period signal low (block 606), and the example program 1102 of FIG. 12 returns to block 1202 and waits for such conditions to be true. On the other hand, when such conditions are met (block 1202), the example activity detection circuitry 202 drives the activity detection period signal high (block 1204). In other words, the conditions of clock inputs are deemed steady-state and efforts to syntonize the clocks begin.

The example activity detection circuitry 202 sets a time-of-day (TOD) value in a precision time protocol (PTP) timer (or other timer/clock) based on the reference clock TOD value (e.g., the example reference clock 222 of FIG. 2, the example GNSS reference clock 116 of FIG. 1, the example 5G reference clock 118 of FIG. 1, the example Ethernet reference clock 120 of FIG. 1, the example media reference clock 122 of FIG. 1, the example host clock 124 of FIG. 1, etc.) (block 1208). The activity detection circuitry 202 generates a synchronized reference clock pulse and a regenerated NCO clock pulse (e.g., phase aligns the NCO clock with the reference clock (e.g., at startup)) based on the reference clock (e.g., primary clock) and the local clock (e.g., secondary clock) (block 1210). As described above, early stages of operation (e.g., after initialization) of the syntonization circuitry 106 exhibit a relatively high likelihood of phase differences between the reference clock and the local clock because PLL tuning has not yet occurred for a sufficient number of clock periods (e.g., a quantity of clock periods that, in the aggregate, allow PLL tuning to have a beneficial effect on phase error differences). Control then returns to block 1104 of FIG. 11.

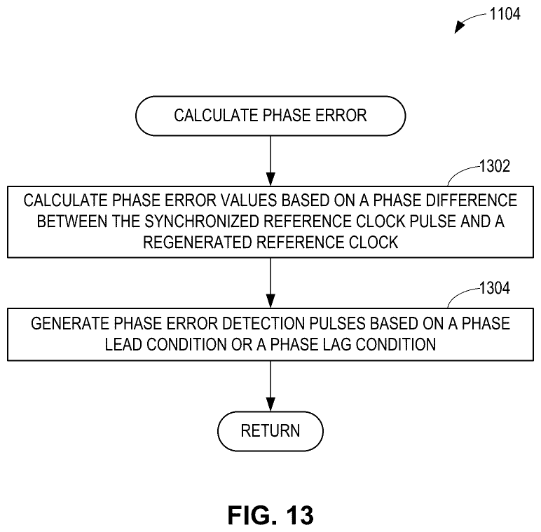

FIG. 13 is a flowchart illustrating an example manner of calculating the phase error of block 1104. In the illustrated example of FIG. 13, the phase error generation circuitry 204 calculates phase error values based on a phase difference between the synchronized reference clock pulse and a regenerated reference clock (block 1302). As described above and in further detail below, the phase error values are provided and/or otherwise transmitted to the frequency lock detection circuitry 206 to determine when a frequency lock condition is true (e.g., when a phase error is below a threshold value). The example phase error generation circuitry 204 generates phase error detection pulses based on whether the reference clock 222 is lagging or leading the regenerated clock 230 (block 1304). In some examples, a raw phase error is returned, and the frequency error accumulator circuitry 112 accumulates phase error over the current reference clock cycle to provide an accumulated phase error value/metric (block 1306). Control then returns to block 1106 of FIG. 11.

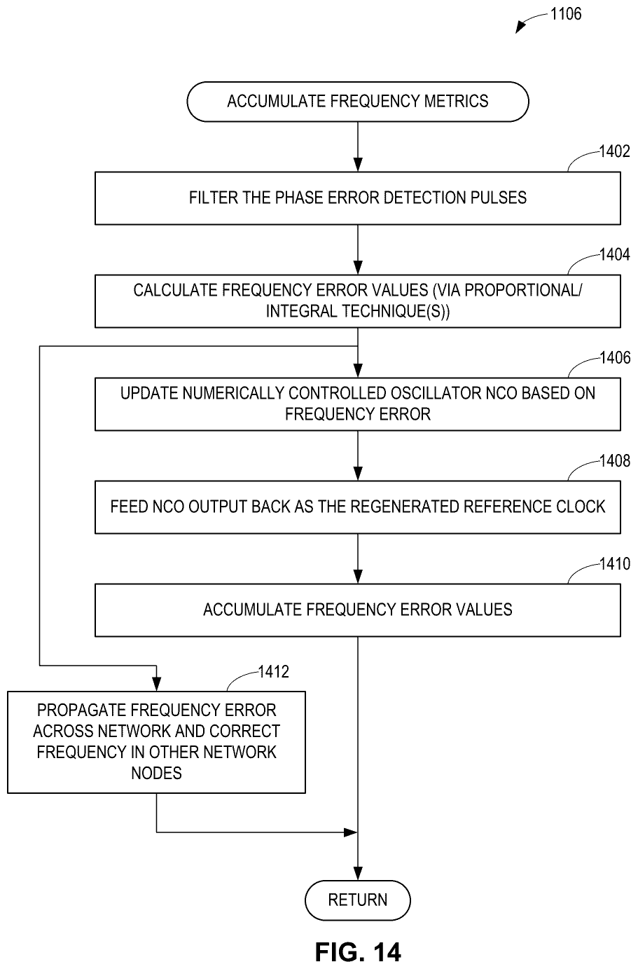

FIG. 14 is a flowchart illustrating additional detail associated with an example manner of accumulating frequency metrics of block 1106. In the illustrated example of FIG. 14, the loop filter circuitry 208 filters the phase error detection pulses (block 1402), and the PI control circuitry 210 calculates frequency error values (block 1404). In some examples, the program of FIG. 14 takes two paths, one of which updates the NCO circuitry 212 (block 1406), and another that propagates frequency error information across one or more networks and corrects frequency in other network nodes (block 1412). Returning to block 1406, based on the frequency error values, the NCO circuitry 212 updates an NCO frequency (block 1406) and feeds the NCO frequency output back to the example phase error generation circuitry 204 as an updated regenerated reference clock (block 1408). Additionally, the frequency error accumulator circuitry 112 retrieves, receives and/or otherwise obtains the frequency error values 238 in the register 216 (block 1410). Control then returns to block 1108 of FIG. 11.

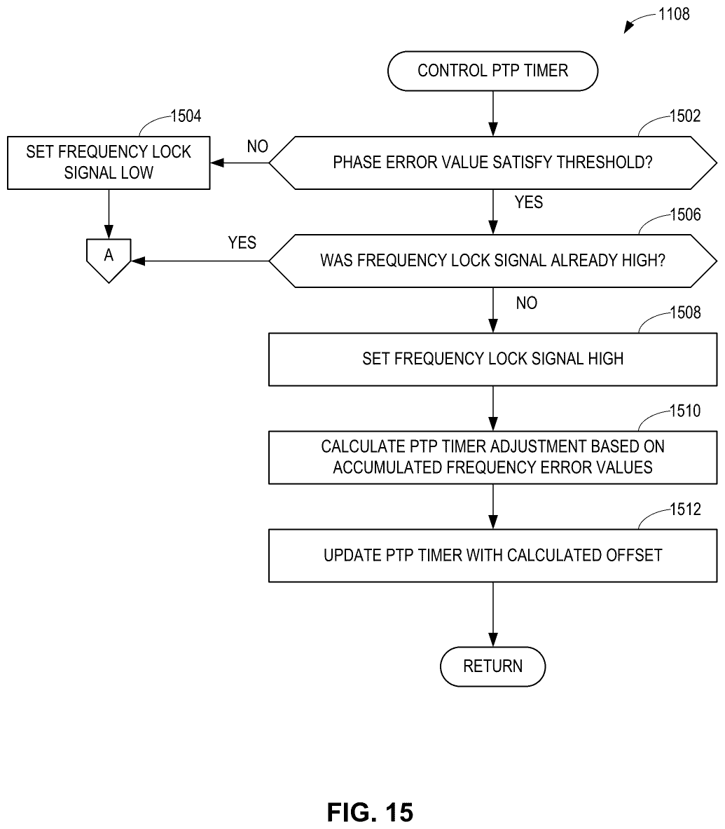

FIG. 15 is a flowchart illustrating additional detail associated with an example manner of controlling a PTP timer of block 1108. In the illustrated example of FIG. 15, the example frequency lock detection circuitry 206 determines whether an accumulated phase error value satisfies a threshold value (block 1502). If not, then the frequency lock detection circuitry 206 sets a frequency lock signal low (e.g., FALSE, 0) (block 1504), and control returns to block 1104 of FIG. 11. However, if the frequency lock detection circuitry 206 determines that the phase error satisfies a threshold value (block 1502) (e.g., the current phase error value is less than the threshold value), then the frequency lock detection circuitry 206 determines whether a prior state of the syntonization circuitry 106 was already in a frequency lock state (block 1506). If so, control returns to block 1104 of FIG. 11 to allow continued monitoring of the phase error to determine if and/or when clock drift occurs to cause a threshold violation.

On the other hand, if the frequency lock detection circuitry 206 determines that the current state of the syntonization circuitry 106 was not in a frequency lock state (block 1506), which was indicative of a prior phase error condition, the frequency lock detection circuitry 206 sets the frequency lock signal to high (block 1508) to identify that the phase error is no longer problematic and/or otherwise out-of-phase. Stated differently, the frequency lock state indicates that any clock drift that may have been present earlier (e.g., after initialization of the syntonization circuitry 106), is now gone and the reference clock 222 and local clock 220 are in phase.

The example overflow/underflow detection circuitry 218 calculates a PTP timer adjustment value based on the accumulated frequency error values stored in the register 216 (block 1510). The example PTP timer circuitry 108 updates and/or otherwise modifies the PTP timer with calculated adjustment/offset (block 1512) and the register 216 continues to update based on incoming data.

As discussed above, some examples disclosed herein, IEEE 1588 compliant PTP clocks are syntonized with a reference clock on an autonomous basis, in which such reference clocks may operate at clock rates in excess of 10 MHz. Example syntonization circuitry 106 disclosed herein may be implemented in a manner that does not require localized CPU software intervention after startup initialization (e.g., computational resources from an on-board NIC), thereby preventing localized CPUs from sacrificing computing resources (e.g., via software attempts to monitor and/or otherwise correct for frequency error(s). Some examples disclosed herein may utilize hardware syntonization approaches in a manner that overcomes software approaches that suffer from relatively longer settling times to correct frequency errors. Additionally, software-based error correction attempts suffer from computational resource competition during task execution, such that relatively higher demands on underlying hardware resources that execute the software-based approach will cause a loss of accuracy when attempting to correct phase errors. As such, some examples disclosed herein permit the localized computational resources to stay focused on timing critical tasks associated with TSN applications.

In addition to syntonization of reference clocks with local clocks, some examples disclosed herein transmit and/or otherwise provide correction pulses to network accessible PTP clocks. In some examples, the correction pulses communicate metadata indicative of relative clock drift across a TSN.

FIG. 16 is a block diagram of example FPGA circuitry 1600. For example, the FPGA circuitry 1600 may be implemented by an FPGA. Once configured, the FPGA circuitry 1600 instantiates the operations and/or functions in hardware and, thus, can often execute the operations/functions faster than they could be performed by a general-purpose microprocessor executing the corresponding software.

More specifically, the FPGA circuitry 1600 of the example of FIG. 16 includes interconnections and logic circuitry that may be configured, structured, programmed, and/or interconnected in different ways after fabrication to instantiate, for example, some or all of the operations/functions corresponding to the flowchart(s) of FIGS. 11-15. In particular, the FPGA circuitry 1600 may be thought of as an array of logic gates, interconnections, and switches. The switches can be programmed to change how the logic gates are interconnected by the interconnections, effectively forming one or more dedicated logic circuits (unless and until the FPGA circuitry 1600 is reprogrammed). The configured logic circuits enable the logic gates to cooperate in different ways to perform different operations on data received by input circuitry. Those operations may correspond to some or all of the operations (e.g., firmware) represented by the flowchart(s) of FIGS. 11-15. As such, the FPGA circuitry 1600 may be configured and/or structured to effectively instantiate some or all of the operations/functions corresponding to the flowchart(s) of FIGS. 11-15 as dedicated logic circuits to perform the operations/functions corresponding to those software instructions in a dedicated manner analogous to an ASIC. Therefore, the FPGA circuitry 1600 may perform the operations/functions corresponding to the some or all of the operations of FIGS. 5-9 faster than a general-purpose microprocessor can execute the same.

In the example of FIG. 16, the FPGA circuitry 1600 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1600 of FIG. 16 may access and/or load the binary file to cause the FPGA circuitry 1600 of FIG. 16 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1600 of FIG. 16 to cause configuration and/or structuring of the FPGA circuitry 1600 of FIG. 16, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1600 of FIG. 16 may access and/or load the binary file to cause the FPGA circuitry 1600 of FIG. 16 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1600 of FIG. 16 to cause configuration and/or structuring of the FPGA circuitry 1600 of FIG. 16, or portion(s) thereof.

The FPGA circuitry 1600 of FIG. 16, includes example input/output (I/O) circuitry 1602 to obtain and/or output data to/from example configuration circuitry 1604 and/or external hardware 1606. For example, the configuration circuitry 1604 may be implemented by interface circuitry that may obtain a binary file, which may be implemented by a bit stream, data, and/or machine-readable instructions, to configure the FPGA circuitry 1600, or portion(s) thereof. In some such examples, the configuration circuitry 1604 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1606 may be implemented by external hardware circuitry.

The FPGA circuitry 1600 also includes an array of example logic gate circuitry 1608, a plurality of example configurable interconnections 1610, and example storage circuitry 1612. The logic gate circuitry 1608 and the configurable interconnections 1610 are configurable to instantiate one or more operations/functions that may correspond to at least some of the operations of FIGS. 11-15 and/or other desired operations. The logic gate circuitry 1608 shown in FIG. 16 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1608 to enable configuration of the electrical structures and/or the logic gates to form circuits to perform desired operations/functions. The logic gate circuitry 1608 may include other electrical structures such as look-up tables (LUTs), registers (e.g., flip-flops or latches), multiplexers, etc.

The configurable interconnections 1610 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1208 to program desired logic circuits.

The storage circuitry 1612 of the illustrated example is structured to store result(s) of the one or more of the operations performed by corresponding logic gates. The storage circuitry 1612 may be implemented by registers or the like. In the illustrated example, the storage circuitry 1612 is distributed amongst the logic gate circuitry 1608 to facilitate access and increase execution speed.

The example FPGA circuitry 1600 of FIG. 16 also includes example dedicated operations circuitry 1614. In this example, the dedicated operations circuitry 1614 includes special purpose circuitry 1616 that may be invoked to implement commonly used functions to avoid the need to program those functions in the field. Examples of such special purpose circuitry 1616 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1600 may also include example general purpose programmable circuitry 1618 such as an example CPU 1620 and/or an example DSP 1622. Other general purpose programmable circuitry 1618 may additionally or alternatively be present such as a GPU, an XPU, etc., that can be programmed to perform other operations.

Although FIG. 16 illustrates one example implementation, many other approaches are contemplated. For example, FPGA circuitry may include an on-board CPU, and may additionally be implemented by combining with the example FPGA circuitry 1600 of FIG. 16. In some such hybrid examples, an ASIC may be configured and/or structured to perform operation(s)/function(s) corresponding to operations represented by the flowcharts of FIGS. 11-15.

It should be understood that some or all of the circuitry of FIG. 2 may, thus, be instantiated at the same or different times. In some examples, same and/or different portion(s) of the FPGA circuitry 1600 of FIG. 16 may be configured and/or structured to perform operations/functions corresponding to portion(s) of machine-readable instructions at the same and/or different times.

In some examples, the FPGA circuitry 1600 of FIG. 16 may be configured and/or structured to carry out operations/functions concurrently and/or in series.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+/−1 nano-second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that syntonize timing devices. Some examples disclosed herein permit relatively less expensive timing device circuitry to be used in, for example, a time-sensitive-network (TSN), thereby maintaining cost effective circuit manufacturing while improving clock syntonization. Examples disclosed herein address secondary clocks (e.g., local clocks) exhibiting drifting errors when crystal-oscillator circuit technologies are implemented by providing techniques to correct secondary clock phase drift due to environmental conditions (e.g., temperature changes, voltage changes, etc.). Some examples disclosed herein improve and/or otherwise correct drift errors in secondary clocks, and permit further correction of network-accessible clocks of a PTP clock system. Disclosed systems, apparatus, articles of manufacture, and methods are accordingly directed to one or more improvement(s) in the operation of a machine such as a computer or other electronic and/or mechanical device.

Example apparatus to syntonize timing devices are disclosed herein. Further examples and combinations thereof include the following:

Example 1 includes an apparatus comprising activity detection circuitry to generate a pulse output based on a first clock and a second clock, the pulse output having a periodicity of the first clock, phase error generation circuitry to determine phase error direction indicators between the pulse output and a regenerated clock, the regenerated clock having a first frequency, proportional/integral (PI) circuitry to determine correction values based on the phase error direction indicators, the correction values to cause modification of the first frequency of the regenerated clock, and precision time protocol (PTP) timer circuitry to modify a frequency of a third clock based on accumulated ones of the correction values.

Example 2 includes the apparatus as defined in example 1, wherein the PI circuitry is to inject the correction values to a numerically controlled oscillator (NCO), the NCO to cause the modification of the first frequency of the regenerated clock.

Example 3 includes the apparatus as defined in any one or more of examples 1-2, including frequency error accumulation circuitry to accumulate the correction values in an accumulator, the correction values indicative of frequency increment metrics or decrement metrics for the third clock.

Example 4 includes the apparatus as defined in any one or more of examples 1-3, including frequency lock detection circuitry to generate a frequency lock trigger based on an accumulated phase error satisfying a phase error threshold.

Example 5 includes the apparatus as defined in example 4, including overflow/underflow detection circuitry to apply the accumulated correction values to the third clock based on the frequency lock trigger, the accumulated correction values indicative of the modified frequency of the third clock.

Example 6 includes the apparatus as defined in example 4, wherein the frequency lock trigger is to cause the PTP timer circuitry to cause transmission of the correction values to a network.

Example 7 includes the apparatus as defined in example 6, wherein the PI circuitry is to cause correction of frequency error of nodes of the network.

Example 8 includes the apparatus as defined in any one or more of examples 1-7, wherein the first clock includes a reference clock and the second clock includes a local clock.

Example 9 includes the apparatus as defined in example 8, wherein the reference clock includes a first frequency resolution higher than a second frequency resolution of the local clock.

Example 10 includes the apparatus as defined in example 8, wherein the third clock includes a Precision Time Protocol (PTP) clock.

Example 11 includes the apparatus as defined in any one or more of examples 1-10, wherein the PTP timer circuitry is to transmit the correction values to time sensitive network (TSN) clocks of network nodes.

Example 12 includes the apparatus as defined in any one or more of examples 1-11, including host circuitry and a network interface controller (NIC), the NIC including at least one of the activity detection circuitry, the phase error generation circuitry, the PI circuitry, the PTP timer circuitry, frequency error accumulation circuitry, frequency lock detection circuitry, overflow/underflow detection circuitry, loop filter circuitry, or numerically controlled oscillator (NCO) circuitry.

Example 13 includes an apparatus comprising means for activity detection to generate a pulse output based on a first clock and a second clock, the pulse output having a periodicity of the first clock, means for phase error generation to determine phase direction indicators between the pulse output and a regenerated clock, the regenerated clock having a first frequency, means for proportional/integral (PI) control to determine correction values based on the phase error direction indicators, the correction values to cause modification of the first frequency of the regenerated clock, and means for overflow/underflow detection to modify a frequency of a third clock based on accumulated ones of the correction values.

Example 14 includes the apparatus as defined in example 13, wherein the means for PI control is to inject the correction values to a numerically controlled oscillator (NCO), the NCO to cause the modification of the first frequency of the regenerated clock.

Example 15 includes the apparatus as defined in any one or more of examples 13-14, including means for error accumulation to accumulate the correction values, the correction values indicative of frequency increment metrics or decrement metrics for the third clock.

Example 16 includes the apparatus as defined in any one or more of examples 13-15, including means for frequency lock detection to generate a frequency lock trigger based on an accumulated phase error satisfying a phase error threshold.

Example 17 includes the apparatus as defined in any one or more of examples 13-16, wherein the means for overflow/underflow detection is to apply the accumulated correction values to the third clock based on the frequency lock trigger, the accumulated correction values indicative of the modified frequency of the third clock.

Example 18 includes the apparatus as defined in any one or more of examples 13-17, including host circuitry and a network interface controller (NIC), the NIC including at least one of the means for phase error generation, the means for PI control, the means for overflow/underflow detection, means for error accumulation, or means for frequency lock detection.

Example 19 includes a method comprising generating a pulse output based on a first clock and a second clock, the pulse output having a periodicity of the first clock, determining phase error direction indicators between the pulse output and a regenerated clock, the regenerated clock having a first frequency, determining correction values based on the phase error direction indicators, the bias to cause modification of the first frequency of the regenerated clock, and modifying a frequency of a third clock based on accumulated ones of the correction values.

Example 20 includes the method as defined in example 19, including injecting the correction values to a numerically controlled oscillator (NCO), the NCO to cause the modification of the first frequency of the regenerated clock.

Example 21 includes the method as defined in any one or more of examples 19-20, including accumulating the correction values in an accumulator, the correction values indicative of frequency increment metrics or decrement metrics for the third clock.

Example 22 includes the method as defined in any one or more of examples 19-21, including generating a frequency lock trigger based on an accumulated phase error satisfying a phase error threshold.

Example 23 includes the method as defined in any one or more of examples 19-22, including applying the accumulated correction values to the third clock based on the frequency lock trigger, the accumulated correction values indicative of the modified frequency of the third clock.

Example 24 includes the method as defined in any one or more of examples 19-23, further including transmitting the correction values to a network based on the frequency lock trigger.

Example 25 includes the method as defined in example 24, including correcting frequency errors associated with nodes of the network.

Example 26 includes the method as defined in any one or more of examples 19-25, wherein the first clock includes a reference clock and the second clock includes a local clock.

Example 27 includes the method as defined in any one or more of examples 19-26, wherein the reference clock includes a first frequency resolution higher than a second frequency resolution of the local clock.

Example 28 includes the method as defined in any one or more of examples 19-26, wherein the third clock includes a Precision Time Protocol (PTP) clock.

Example 29 includes the method as defined in any one or more of examples 19-28, including transmitting the correction values to time sensitive network (TSN) clocks of network nodes.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
activity detection circuitry to generate a pulse output based on a first clock and a second clock, the pulse output having a periodicity of the first clock;
phase error generation circuitry to determine phase error direction indicators between the pulse output and a regenerated clock, the regenerated clock having a first frequency;
proportional/integral (PI) circuitry to determine correction values based on the phase error direction indicators, the correction values to cause modification of the first frequency of the regenerated clock; and
precision time protocol (PTP) timer circuitry to modify a frequency of a third clock based on accumulated ones of the correction values.

2. The apparatus as defined in claim 1, wherein the PI circuitry is to inject the correction values to a numerically controlled oscillator (NCO), the NCO to cause the modification of the first frequency of the regenerated clock.

3. The apparatus as defined in claim 1, including frequency error accumulation circuitry to accumulate the correction values in an accumulator, the correction values indicative of frequency increment metrics or decrement metrics for the third clock.

4. The apparatus as defined in claim 3, including frequency lock detection circuitry to generate a frequency lock trigger based on an accumulated phase error satisfying a phase error threshold.

5. The apparatus as defined in claim 4, including overflow/underflow detection circuitry to apply the accumulated correction values to the third clock based on the frequency lock trigger, the accumulated correction values indicative of the modified frequency of the third clock.

6. The apparatus as defined in claim 4, wherein the frequency lock trigger is to cause the PTP timer circuitry to cause transmission of the correction values to a network.

7. The apparatus as defined in claim 6, wherein the PI circuitry is to cause correction of frequency error of nodes of the network.

8. The apparatus as defined in claim 1, wherein the first clock includes a reference clock and the second clock includes a local clock.

9. The apparatus as defined in claim 8, wherein the reference clock includes a first frequency resolution higher than a second frequency resolution of the local clock.

10. The apparatus as defined in claim 8, wherein the third clock includes a Precision Time Protocol (PTP) clock.

11. The apparatus as defined in claim 1, including host circuitry and a network interface controller (NIC), the NIC including at least one of the activity detection circuitry, the phase error generation circuitry, the PI circuitry, the PTP timer circuitry, frequency error accumulation circuitry, frequency lock detection circuitry, overflow/underflow detection circuitry, loop filter circuitry, or numerically controlled oscillator (NCO) circuitry.

12. An apparatus comprising:
means for activity detection to generate a pulse output based on a first clock and a second clock, the pulse output having a periodicity of the first clock;
means for phase error generation to determine phase direction indicators between the pulse output and a regenerated clock, the regenerated clock having a first frequency;
means for proportional/integral (PI) control to determine correction values based on the phase error direction indicators, the correction values to cause modification of the first frequency of the regenerated clock; and
means for overflow/underflow detection to modify a frequency of a third clock based on accumulated ones of the correction values.

13. The apparatus as defined in claim 12, wherein the means for PI control is to inject the correction values to a numerically controlled oscillator (NCO), the NCO to cause the modification of the first frequency of the regenerated clock.

14. The apparatus as defined in claim 12, including means for error accumulation to accumulate the correction values, the correction values indicative of frequency increment metrics or decrement metrics for the third clock.

15. The apparatus as defined in claim 14, including means for frequency lock detection to generate a frequency lock trigger based on an accumulated phase error satisfying a phase error threshold.

16. The apparatus as defined in claim 15, wherein the means for overflow/underflow detection is to apply the accumulated correction values to the third clock based on the frequency lock trigger, the accumulated correction values indicative of the modified frequency of the third clock.

17. The apparatus as defined in claim 12, including host circuitry and a network interface controller (NIC), the NIC including at least one of the means for phase error generation, the means for PI control, the means for overflow/underflow detection, means for error accumulation, or means for frequency lock detection.

18. A method comprising:
generating a pulse output based on a first clock and a second clock, the pulse output having a periodicity of the first clock;
determining phase error direction indicators between the pulse output and a regenerated clock, the regenerated clock having a first frequency;
determining correction values based on the phase error direction indicators, the correction values to cause modification of the first frequency of the regenerated clock; and
modifying a frequency of a third clock based on accumulated ones of the correction values.

19. The method as defined in claim 18, including injecting the correction values to a numerically controlled oscillator (NCO), the NCO to cause the modification of the first frequency of the regenerated clock.

20. The method as defined in claim 18, including accumulating the correction values in an accumulator, the correction values indicative of frequency increment metrics or decrement metrics for the third clock.
